(19) United States
(12) Patent Application Publication
(10) Pub. No.: US 2025/0234111 A1
(43) Pub. Date: Jul. 17, 2025

(54) IMAGE SENSING DEVICE

(71) Applicant: SK hynix Inc., Icheon-si (KR)

(72) Inventors: Gon Ji LEE, Icheon-si (KR); Hyung Jun HAN, Icheon-si (KR)

(21) Appl. No.: 18/959,360

(22) Filed: Nov. 25, 2024

(30) Foreign Application Priority Data
Jan. 16, 2024 (KR) 10-2024-0006816

(51) Int. Cl. H04N 25/778; H04N 25/616; H04N 25/76

(52) U.S. Cl. CPC H04N 25/778; H04N 25/7795; H04N 25/616

(57) ABSTRACT

The image sensing device includes a transfer signal output node; a pull-up driver configured to pull up a voltage level of the transfer signal output node to a first charge pumping voltage based on a pull-up control signal applied to the pull-up driver; a first pull-down driver configured to pull down the voltage level of the transfer signal output node at a first pull-down speed based on a first pull-down control signal applied to the first pull-down driver; a switching circuit configured to selectively connect the transfer signal output node to either the pull-up driver or the first pull-down driver based on a switching control signal applied to the switching circuit; and a second pull-down driver coupled to the transfer signal output node and configured to pull down the voltage level of the transfer signal output node at a second pull-down speed based on a second pull-down control signal.

### CROSS-REFERENCE TO RELATED APPLICATION

This patent document claims the priority and benefits of Korean patent application No. 10-2024-0006816, filed on Jan. 16, 2024, which is incorporated by reference in its entirety as part of the disclosure of this patent document.

### TECHNICAL FIELD

The technology and implementations disclosed in this patent document generally relate to an image sensing device including a transfer transistor of a pixel.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

### SUMMARY

Various embodiments of the disclosed technology relate to an image sensing device capable of improving spillback characteristics that may occur in a transfer transistor of a pixel.

In accordance with an embodiment of the disclosed technology, an image sensing device may include a transfer signal output node coupled to output an electrical signal, a pull-up driver configured to pull up a voltage level of the transfer signal output node to a first charge pumping voltage based on a pull-up control signal applied to the pull-up driver, a first pull-down driver configured to pull down the voltage level of the transfer signal output node at a first pull-down speed based on a first pull-down control signal applied to the first pull-down driver, a switching circuit configured to selectively connect the transfer signal output node to either the pull-up driver or the first pull-down driver based on a switching control signal applied to the switching circuit, and a second pull-down driver coupled to the transfer signal output node and configured to pull down the voltage level of the transfer signal output node at a second pull-down speed different from the first pull-down speed based on a second pull-down control signal.

In accordance with another embodiment of the disclosed technology, an image sensing device may include a photoelectric conversion element configured to generate photocharges through a photoelectric conversion of incident light, a floating diffusion node configured to receive the photocharges from the photoelectric conversion element and accumulate the photocharges, a transfer transistor coupled to the photoelectric conversion element and the floating diffusion node and configured to transmit the photocharges generated by the photoelectric conversion element to the floating diffusion node based on a transfer signal; and a row driver configured to generate the transfer signal and provide the transfer signal to the transfer transistor, wherein the row driver is configured to change a pull-down speed at which the transfer signal is being pulled down from a first charge pumping voltage to a second charge pumping voltage.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a schematic diagram illustrating an example structure of an image sensing device based on some implementations of the disclosed technology.

FIG. 2 is a circuit diagram illustrating an example structure of a unit pixel formed in a pixel array shown in FIG. 1 based on some implementations of the disclosed technology.

FIG. 3 is a circuit diagram illustrating an example structure of a circuit for enabling a row driver shown in FIG. 1 to generate a transfer signal based on some implementations of the disclosed technology.

FIG. 4 is a timing diagram illustrating examples of control signals applied to the row driver shown in FIG. 1 based on some implementations of the disclosed technology.

FIG. 5 is an example of a diagram illustrating how a falling slope changes when a transfer signal is pulled down based on some implementations of the disclosed technology.

FIG. 6 is a circuit diagram illustrating another example structure of a circuit for enabling the row driver shown in FIG. 1 to generate/output a transfer signal based on some implementations of the disclosed technology.

### DETAILED DESCRIPTION

This patent document provides implementations and examples of an image sensing device that may be used to substantially address one or more technical or engineering issues and mitigate limitations or disadvantages encountered in some other image sensing devices. Some implementations of the disclosed technology suggest examples of an image sensing device capable of improving spillback characteristics that may occur in a transfer transistor of a pixel. In recognition of the issues above, the disclosed technology provides various implementations of an image sensing device capable of improving spillback characteristics that may occur in a transfer transistor of a pixel.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

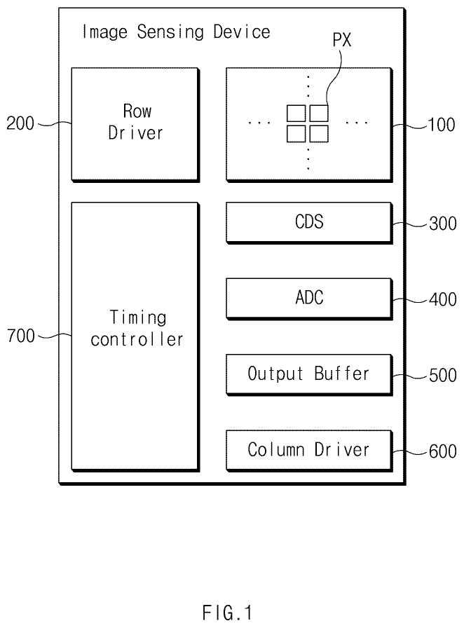

FIG. 1 is a block diagram illustrating an example of an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600, and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The pixel array 100 may include a plurality of unit pixels (PXs) arranged in rows and columns. In one example, the plurality of unit pixels (PXs) can be arranged in a two dimensional (2D) pixel array including rows and columns. The plurality of unit pixels (PXs) may convert incident light into electrical signals (pixel signals) on a unit pixel basis, and may output the electrical signals (pixel signals). Each unit pixel (PX) may include a photoelectric conversion element that generates photocharges through photoelectric conversion of the incident light. The photoelectric conversion element may include a photodiode, a phototransistor, a photogate, a pinned photodiode, or a combination thereof.

The pixel array 100 may receive driving signals (for example, a row selection signal, a reset signal, a transmission (or transfer) signal, etc.) from the row driver 200. Upon receiving the driving signals, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more unit pixels arranged in one or more rows of the pixel array 100. The row driver 200 may generate a row selection signal to select one or more rows from among the plurality of rows.

The row driver 200 may operate the unit pixels of the selected row line by providing a reset signal and a transfer signal to the unit pixels. When generating the transfer signal, the row driver 200 may gradually change a falling slope (pull-down speed) of the transfer signal while the transfer signal is being pulled down. As a result, the row driver 200 can improve spillback characteristics that may occur in the transfer transistor. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, and may select a column of the output buffer 500 using the column selection signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

In some implementations, the timing controller 700 may include a logic control circuit, a phase lock loop (PLL) circuit, a timing control circuit, a communication interface circuit and others.

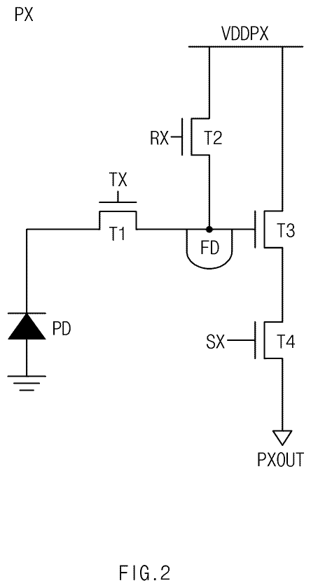

FIG. 2 is a circuit diagram illustrating an example structure of a unit pixel (PX) formed in the pixel array 100 shown in FIG. 1 based on some implementations of the disclosed technology.

Referring to FIG. 2, the unit pixel (PX) of the pixel array 110 may include a photoelectric conversion element PD, a transfer transistor T1, a reset transistor T2, a drive transistor T3, and a selection transistor T4.

The photoelectric conversion element PD may generate and accumulate photocharges corresponding to incident light. For example, the photoelectric conversion element PD may include a photodiode, a phototransistor, a photogate, a pinned photodiode (PPD), or a combination thereof, but is not limited thereto.

The transfer transistor T1 may transmit photocharges accumulated in the photoelectric conversion element PD to a floating diffusion node FD based on the transfer signal TX. For example, the transfer transistor T1 may include an NMOS transistor that receives a transfer signal TX through a gate terminal thereof and is connected to the floating diffusion node FD through source/drain terminals thereof.

The floating diffusion node FD may receive and accumulate photocharges generated by the photoelectric conversion element PD. The drive transistor T3 may be controlled based on the amount of photocharges accumulated in the floating diffusion node FD.

The reset transistor T2 may periodically reset the floating diffusion node FD. When the reset signal RX is enabled and the reset transistor T2 is turned on, a first pixel power-supply voltage (VDDPX) is transferred to the floating diffusion node FD. Accordingly, photocharges accumulated in the floating diffusion node FD may be discharged such that the floating diffusion node FD can be reset. For example, the reset transistor T2 may include an NMOS transistor that receives the reset signal RX through a gate terminal thereof and is connected to the floating diffusion node FD and first pixel power-supply voltage (VDDPX) node.

The drive transistor T3 may be or include a source follower buffer amplifier that generates a source-drain current in proportion to the amount of charges of the floating diffusion node FD. The drive transistor T3 may amplify a change in potential at the floating diffusion node FD, and the amplified signal may be output to an output line (column line) through the selection transistor T4. For example, the drive transistor T3 may include an NMOS transistor that is connected to the floating diffusion node (FD) through a gate terminal of the NMOS transistor and is connected to the first pixel power-supply voltage (VDDPX) node and the selection transistor T4.

The selection transistor T4 may output the pixel signal (PXOUT) to the column line based on the row selection signal SX. For example, the selection transistor T4 may include an NMOS transistor that receives the row selection signal SX through a gate terminal of the NMOS transistor and is connected to the drive transistor T3 and the column line.

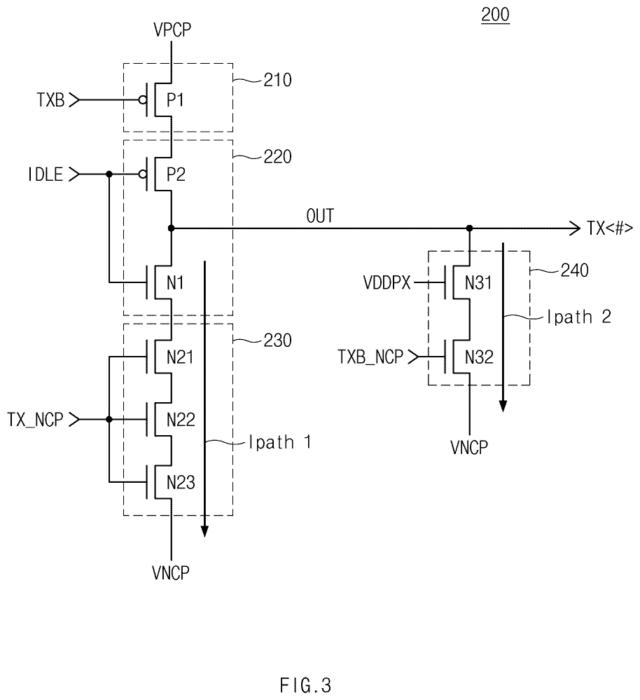

FIG. 3 is a circuit diagram illustrating an example structure of a circuit for enabling the row driver 200 shown in FIG. 1 to generate a transfer signal based on some implementations of the disclosed technology.

Referring to FIG. 3, the row driver 200 may include a pull-up driver 210, a pull-up/pull-down switching circuit 220, a first pull-down driver 230, and a second pull-down driver 240.

The pull-up driver 210 may pull up a voltage of a transfer signal output node (OUT) to a preset positive charge pumping (PCP) voltage (VPCP) level based on a pull-up control signal (TXB). The pull-up control signal (TXB) may be activated when the pull-up/pull-down switching circuit 220 is turned on and the pull-up driver 210 is connected to the transfer signal output node (OUT), thereby operating the pull-up driver 210. For example, the pull-up control signal (TXB) may be a signal having a phase opposite to that of the transfer signal (TX) to be generated.

The pull-up driver 210 may include a PCP voltage (VPCP) node and a switching element P1 connected to the pull-up/pull-down switching circuit 220. For example, the switching element P1 may include a PMOS transistor that receives the pull-up control signal (TXB) through a gate terminal of the PMOS transistor and is connected to the PCP voltage (VPCP) node and the pull-up/pull-down switching circuit 220.

The pull-up/pull-down switching circuit 220 may selectively connect the transfer signal output node (OUT) to the pull-up driver 210 or the first pull-down driver 230 based on a switching control signal (IDLE). For example, the pull-up/pull-down switching circuit 220 may connect the pull-up driver 210 to the transfer signal output node (OUT) when the switching control signal (IDLE) is at a low level, and may connect the first pull-down driver 230 to the transfer signal output node (OUT) when the switching control signal (IDLE) is at a high level.

The pull-up/pull-down switching circuit 220 may include a first switching element P2 connected to the pull-up driver 210 and the transfer signal output node (OUT), and a second switching element N1 connected to the first pull-down driver 230 and the transfer signal output node (OUT). For example, the first switching element P2 may include a first transistor, e.g., a PMOS transistor, that receives the switching control signal (IDLE) through a gate terminal of the PMOS transistor and is connected to the pull-up driver 210 and the transfer signal output node (OUT), and the second switching element N1 may include a second transistor, e.g., an NMOS transistor, that receives the switching control signal (IDLE) through a gate terminal of the NMOS transistor and is connected to the first pull-down driver 230 and the transfer signal output node (OUT). The switching control signal (IDLE) may transition from a high level to a low level before a predetermined time from a specific time at which the pull-up control signal (TXB) transitions to a low level, and may transition to a high level when the pull-up control signal (TXB) is at a low level.

The first pull-down driver 230 may enable the voltage of the transfer signal output node (OUT) to be pulled down to a second pixel power-supply voltage (VSSPX) level along a first falling slope (e.g., a first pull-down speed) based on a first pull-down control signal (TX_NCP) applied to the first pull-down driver 230. In implementations, the first pull-down control signal (TX_NCP) may be a signal having a phase opposite to that of the pull-up control signal (TXB).

The first pull-down driver 230 may include switching elements (N21, N22, N23) connected in series between a negative charge pumping (NCP) voltage (VNCP) node and the pull-up/pull-down switching circuit 220 along a first electrical current path Ipath 1. For example, each of the switching elements (N21, N22, N23) may include an NMOS transistor that receives the first pull-down control signal (TX_NCP) through a gate terminal of the NMOS transistor and is connected in series between the NCP voltage (VNCP) node and the pull-up/pull-down switching circuit 220.

The NMOS transistors (N21, N22, N23) may be formed to have the same size. For example, the NMOS transistors (N21, N22, N23) may have substantially the same channel resistance.

Although the present embodiment has disclosed an example case in which the first pull-down driver 230 includes three NMOS transistors (N21, N22, N23) connected in series, the scope of the present embodiment is not limited thereto, and it should be noted that the number of such NMOS transistors within the first pull-down driver 230 may vary depending on how the first falling slope is determined.

The second pull-down driver 240 may be directly coupled to the transfer signal output node (OUT) without a switching circuitry therebetween, e.g., via a conductive line coupled to the transfer signal output node (OUT). The second pull-down driver 240 may be operated to pull down the voltage of the transfer signal output node (OUT) to the NCP voltage (VNCP) level based on the first pixel power supply voltage (VDDPX) and a second pull-down control signal (TXB_NCP) that is fed or applied to the second pull-down driver 240. Here, the second falling slope may be a slope that changes more rapidly than the first falling slope. That is, the second pull-down driver 240 may pull down the transfer signal output node (OUT) at a higher speed than the pulling down operation of the first pull-down driver 230. The second pull-down control signal (TXB_NCP) may be a signal having a phase opposite to that of the first pull-down control signal (TX_NCP).

The second pull-down driver 240 may include switching elements (N31, N32) connected in series between the NCP voltage (VNCP) node and the transfer signal output node (OUT) along a second electrical current path Ipath 2. For example, the switching elements N31 and N32 may include NMOS transistors, respectively. The NMOS transistor N31 may be connected to the transfer signal output node (OUT) and the NMOS transistor N32, and may receive the first pixel power-supply voltage (VDDPX) through a gate terminal of the NMOS transistor N31.

Since the first pixel power-supply voltage (VDDPX) is a positive (+) voltage, the NMOS transistor N31 may remain as being turned on. The NMOS transistor N32 may be connected to the NMOS transistor N31 and the NCP voltage (VNCP) node, and may receive the second pull-down control signal (TXB_NCP) through a gate terminal of the NMOS transistor N32.

The NMOS transistors (N31, N32) may be formed to have the same size as the NMOS transistors (N21, N22, N23) of the first pull-down driver 230. For example, each of the NMOS transistors (N31, N32) may have channel resistance that is substantially the same as channel resistance of each of the NMOS transistors (N21, N22, N23). Under this design, the total resistance of the second electrical current path Ipath 2 between the transfer signal output node (OUT) and the bottom terminal for VNCP of the second pull-down driver 240 with 2 NMOS transistors in series is less than the total resistance of the first electrical current path Ipath 1 formed between the transfer signal output node (OUT) and the bottom terminal for VNCP of the first pull-down driver 230 with 3 NMOS transistors in series.

The pull-down speed of the transfer signal output node (OUT) may be determined based on the resistance of each of current paths (Ipath 1, Ipath 2) between the transfer signal output node (OUT) and the NCP voltage (VNCP) node. In the present embodiment, since the channel resistance of the current path (Ipath 1) is greater than the channel resistance of the current path (Ipath 2), the pull-down speed by the first pull-down driver 230 is less than the pull-down speed by the second pull-down driver 240.

Control signals (TXB, IDLE, TX_NCP, TXB_NCP) may be provided from the timing controller 700.

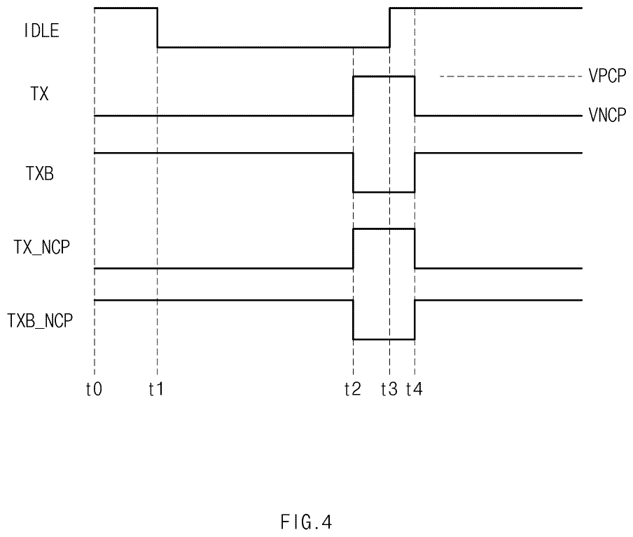

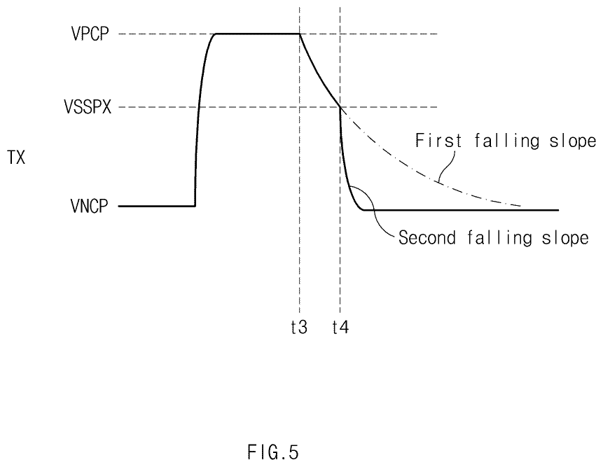

FIG. 4 is a timing diagram illustrating examples of control signals applied to the row driver 200 shown in FIG. 1 based on some implementations of the disclosed technology. FIG. 5 is a diagram illustrating how the falling slope changes when a transfer signal is pulled down based on some implementations of the disclosed technology.

Referring to FIGS. 4 and 5, at a timing point (t0), the pull-up driver 210 and the first pull-down driver 230 may not operate and only the second pull-down driver 240 may operate. In this case, the transfer signal output node (OUT) may transition to the NCP voltage (VNCP) level by the second pull-down driver 240. Accordingly, the transfer signal (TX) may reach the NCP voltage (VNCP) level.

Afterwards, at a timing point (t1), when the switching control signal (IDLE) transitions to the low level and the PMOS transistor P2 is turned on, the pull-up/pull-down switching circuit 220 may connect the pull-up driver 210 to the transfer signal output node (OUT).

Thereafter, at a timing point (t2), the pull-up control signal (TXB) and the second pull-down control signal (TXB_NCP) may transition from a high level to a low level, and the first pull-down control signal (TX_NCP) may transition from a low level to a high level.

As a result, the NMOS transistor N32 of the second pull-down driver 240 is turned off, the pull-down operation is stopped, and the PMOS transistor P1 of the pull-up driver 210 is turned on, so that the transfer signal output node (OUT) can be pulled up to the PCP voltage (VPCP) level by the pull-up driver 210. At this time, the first pull-down driver 230 may not operate because the NMOS transistor N1 of the pull-up/pull-down switching circuit 220 remains as being turned off. Accordingly, the transfer signal TX may transition from the NCP voltage (VNCP) level to the PCP voltage (VPCP) level.

Afterwards, at a timing point (t3), the switching control signal (IDLE) may transition to a high level. For example, the switching control signal (IDLE) may first transition to a high level right before the second pull-down control signal (TXB_NCP) transitions to a high level again. As a result, although the pull-up driver 210 is still operating, connection between the pull-up driver 210 and the transfer signal output node (OUT) is severed by the pull-up/pull-down switching circuit 220 and the first pull-down driver 230 is connected to the transfer signal output node (OUT), so that the transfer signal output node (OUT) may be pulled down with the first falling slope by the first pull-down driver 230.

At this time, since the first pull-down driver 230 has a plurality of NMOS transistors (N21, N22, N23) connected in series, channel resistance of the current path (Ipath 1) through the first pull-down driver 230 is greater than channel resistance of the current path (Ipath 2) through the second pull-down driver 240. Accordingly, the transfer signal output node (OUT) may be pulled down more slowly as compared to the case when pulled down by the second pull-down driver 240.

Thereafter, at a timing point (t4), the first pull-down control signal (TX_NCP) transitions to a low level and the second pull-down control signal (TXB_NCP) transitions to a high level, so that the transfer signal output node (OUT) can be rapidly pulled down with a second falling slope by the second pull-down driver 240.

For example, during a time period from t3 to t4 as shown in FIG. 5, the transfer signal (TX) may be slowly pulled down to the second pixel power-supply voltage (VSSPX) along the first falling slope by the first pull-down driver 230. After lapse of the timing point (t4), the transfer signal (TX) may be rapidly pulled down to the NCP voltage (VNCP) level along the second falling slope by the second pull-down driver 240 as compared to when it is pulled down by the first pull-down driver 230. In the implementations, the pull-down speed at which the transfer signal is pulled down has different values at the time period from t3 to t4 and the time period after t4.

As shown in FIG. 2 described above, while photocharges converted and accumulated in the photoelectric conversion element PD are transmitted to the floating diffusion node FD by the transfer transistor T1, the transfer signal (TX) transitions too quickly to the NCP voltage (VNCP) level, so that there may occur the spillback phenomenon in which not all photocharges present in the channel region of the transfer transistor T1 are transferred to the floating diffusion node FD and some photocharges return to the photoelectric conversion element PD.

However, according to the present embodiment, while the transfer signal (TX) is pulled down to the NCP voltage (VNCP) level, the transfer signal (TX) is controlled to be slowly pulled down for a predetermined period of time only at the initial pull-down stage without being immediately and quickly pulled down to the NCP voltage (VNCP) level, so that occurrences of the spillback phenomenon can be minimized.

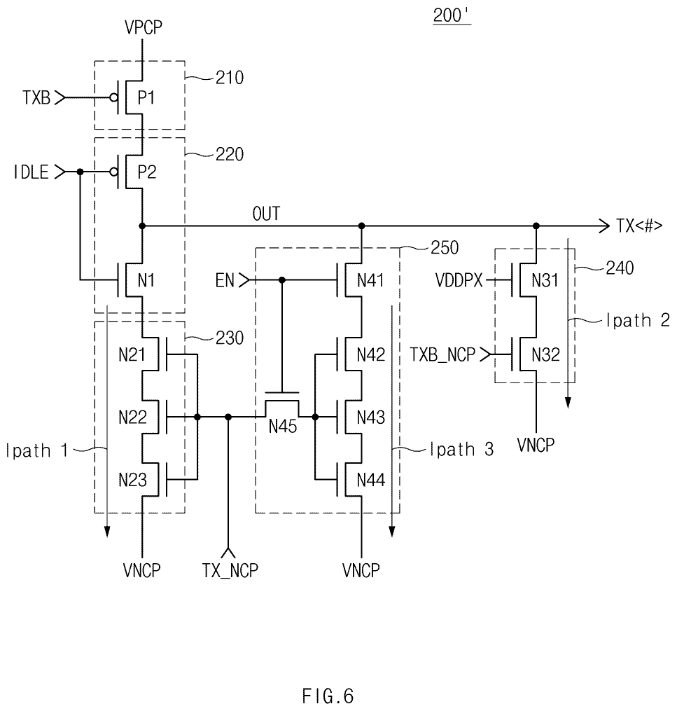

FIG. 6 is a circuit diagram illustrating another example structure of a circuit for enabling the row driver shown in FIG. 1 to output the transfer signal based on some implementations of the disclosed technology.

Referring to FIG. 6, the row driver 200′ may include a pull-up driver 210, a pull-up/pull-down switching circuit 220, a first pull-down driver 230, a second pull-down driver 240, and a third pull-down driver 250.

Unlike the row driver 200 as shown in FIG. 3, the row driver 200′ of FIG. 6 may further include a third pull-down driver 250. The following description will focus on the configuration and operation of the third pull-down driver 250. In addition, the same reference numerals are assigned to the same components as those of the row driver 200 of FIG. 3, and as such redundant description thereof will herein be omitted.

The third pull-down driver 250 may be selectively connected in parallel to the first pull-down driver 230 based on a third pull-down control signal (EN), so that the third pull-down driver 250 together with the first pull-down driver 230 may pull down the voltage of the transfer signal output node (OUT). The third pull-down control signal (EN) may be selectively activated to increase the pull-down speed of the transfer signal output node (OUT). For example, the third pull-down control signal (EN) may be selectively activated to a high level at a timing point (t3) shown in FIG. 4.

The third pull-down driver 250 may include NMOS transistors (N41, N42, N43, N44) connected in series between the transfer signal output node (OUT) and the NCP voltage (VNCP) node along a third electrical current path Ipath 3. In addition, the third pull-down driver 250 may include an NMOS transistor N45 that is connected to gate terminals of the NMOS transistors (N42, N43, N44) and gate terminals of the NMOS transistors (N21, N22, N23) of the first pull-down driver 230.

For example, when the third pull-down control signal (EN) is activated to a high level at the timing point (t3) shown in FIG. 4, the NMOS transistor N41 is turned on and the NMOS transistor N45 is also turned on, such that a first pull-down control signal (TX_NCP) can also be applied to gate terminals of the NMOS transistors (N42, N43, N44). As a result, during a time period from t3 to t4, the first pull-down driver 230 and the third pull-down driver 250 are simultaneously driven, and the transfer signal output node (OUT) may be pulled down more rapidly than the other case in which only the first pull-down driver 230 is driven. Thus, in the implementations, the third pull-down driver 250 operates together with the first pull-down driver 230 to pull down the transfer signal and the pull-down speed at which the transfer signal is pulled down increases as compared to the case the first pull-down driver 230 operates without the third pull-down driver 250.

The third pull-down driver 250 may pull down the transfer signal output node (OUT) at the same pull-down speed as the first pull-down driver 230. The speed at which the first pull-down driver 230 and the third pull-down driver 250 pull down the transfer signal output node (OUT) may be less than the speed at which the second pull-down driver 240 pulls down the transfer signal output node (OUT). The third pull-down driver 250 may pull down the transfer signal output node (OUT) at a pull-down speed different from that of the first pull-down driver 230. In this case, the speed at which the first pull-down driver 230 and the third pull-down driver 250 pull down the transfer signal output node (OUT) may be less than the speed at which the second pull-down driver 240 pulls down the transfer signal output node (OUT).

In some implementations, the NMOS transistors (N41, N42, N43, N44) of the third pull-down driver 250 may be formed to have the same size as the NMOS transistors (N21, N22, N23) of the first pull-down driver 230. For example, each of the NMOS transistors (N41, N42, N43, N44) may have channel resistance that is substantially the same as channel resistance of each of the NMOS transistors (N21, N22, N23).

In some other implementations, the NMOS transistors (N41, N42, N43, N44) of the third pull-down driver 250 may also be formed to have different sizes from the NMOS transistors (N21, N22, N23) of the first pull-down driver 230.

As is apparent from the above description, the image sensing device based on some implementations of the disclosed technology may improve spillback characteristics that may occur in a transfer transistor of a pixel.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a transfer signal output node coupled to output an electrical signal;
a pull-up driver configured to pull up a voltage level of the transfer signal output node to a first charge pumping voltage based on a pull-up control signal applied to the pull-up driver;
a first pull-down driver configured to pull down the voltage level of the transfer signal output node at a first pull-down speed based on a first pull-down control signal applied to the first pull-down driver;
a switching circuit configured to selectively connect the transfer signal output node to either the pull-up driver or the first pull-down driver based on a switching control signal applied to the switching circuit; and
a second pull-down driver coupled to the transfer signal output node and configured to pull down the voltage level of the transfer signal output node at a second pull-down speed different from the first pull-down speed based on a second pull-down control signal.

2. The image sensing device according to claim 1, wherein the second pull-down driver is configured to:
pull down the transfer signal output node to a second charge pumping voltage at a higher speed than the first pull-down speed.

3. The image sensing device according to claim 2, wherein the first pull-down driver is configured to:
pull down the transfer signal output node to a voltage level between the first charge pumping voltage and the second charge pumping voltage.

4. The image sensing device according to claim 3, wherein the second pull-down driver is configured to:
pull down the transfer signal output node, which has been pulled down by the first pull-down driver, to the second charge pumping voltage.

5. The image sensing device according to claim 1, wherein the switching circuit includes:
a first switching element connected to the pull-up driver and the transfer signal output node, and configured to receive the switching control signal through a gate terminal of the first switching element; and
a second switching element connected to the first pull-down driver and the transfer signal output node, and configured to receive the switching control signal through a gate terminal of the second switching element.

6. The image sensing device according to claim 5, wherein the pull-up driver includes:
a third switching element connected to the first switching element and a first charge pumping voltage node, and configured to receive the pull-up control signal through a gate terminal of the third switching element.

7. The image sensing device according to claim 5, wherein the first pull-down driver includes:
a plurality of fourth switching elements connected in series between the second switching element and a second charge pumping voltage node, and configured to commonly receive the first pull-down control signal through gate terminals of the plurality of fourth switching elements.

8. The image sensing device according to claim 1, wherein the second pull-down driver includes:
a first switching element having one terminal connected to the transfer signal output node, and configured to receive a pixel power-supply voltage through a gate terminal of the first switching element; and
a second switching element connected to the first switching element and a second charge pumping voltage node, and configured to receive the second pull-down control signal through a gate terminal of the second switching element.

9. The image sensing device according to claim 1, further comprising:
a third pull-down driver selectively connected in parallel to the first pull-down driver based on a third pull-down control signal, and configured to pull down the voltage level of the transfer signal output node together with the first pull-down driver.

10. The image sensing device according to claim 9, wherein the third pull-down driver includes:
a first switching element having one terminal connected to the transfer signal output node, and configured to receive the third pull-down control signal through a gate terminal of the first switching element; and
a plurality of second switching elements connected in series between the first switching element and a second charge pumping voltage node, and configured to receive the first pull-down control signal through gate terminals of the plurality of second switching elements.

11. The image sensing device according to claim 10, further comprising:
a third switching element configured to selectively transmit the first pull-down control signal to gate terminals of the plurality of second switching elements based on the third pull-down control signal.

12. The image sensing device according to claim 9, wherein the third pull-down driver is configured to:
pull down the voltage level of the transfer signal output node at the first pull-down speed.

13. An image sensing device comprising:
a photoelectric conversion element configured to generate photocharges through a photoelectric conversion of incident light;
a floating diffusion node configured to receive the photocharges from the photoelectric conversion element and accumulate the photocharges;
a transfer transistor coupled to the photoelectric conversion element and the floating diffusion node, and configured to transmit the photocharges generated by the photoelectric conversion element to the floating diffusion node based on a transfer signal; and
a row driver configured to generate the transfer signal and provide the transfer signal to the transfer transistor,
wherein the row driver is configured to change a pull-down speed at which the transfer signal is being pulled down from a first charge pumping voltage to a second charge pumping voltage.

14. The image sensing device according to claim 13, wherein the row driver includes:
a pull-up driver configured to pull up a voltage level of a transfer signal output node to the first charge pumping voltage based on a pull-up control signal; and
a pull-down driver configured to gradually pull down the voltage level of the transfer signal output node at different pull-down speeds based on a first pull-down control signal and a second pull-down control signal.

15. The image sensing device according to claim 14, wherein the pull-down driver includes:
a first pull-down driver configured to pull down the voltage level of the transfer signal output node to a pixel power-supply voltage level at a first pull-down speed based on the first pull-down control signal; and
a second pull-down driver configured to pull down the transfer signal output node that has been pulled down to the pixel power-supply voltage level to the second charge pumping voltage at a second pull-down speed higher than the first pull-down speed based on the second pull-down control signal.

16. The image sensing device according to claim 15, further comprising:
a third pull-down driver selectively connected in parallel to the first pull-down driver based on a third pull-down control signal, and configured to pull down the transfer signal output node together with the first pull-down driver.

17. The image sensing device according to claim 15, further comprising:
a switching circuit configured to selectively connect any one of the pull-up driver and the first pull-down driver to the transfer signal output node based on a switching control signal.

18. The image sensing device according to claim 15, wherein a resistance of a first current path flowing through the first pull-down driver is greater than a resistance of a second current path flowing through the second pull-down driver.

19. The image sensing device according to claim 16, wherein the first pull-down driver and the third pull-down driver are configured to pull down the transfer signal output node at a third pull-down speed that is greater than the first pull-down speed and smaller than the second pull-down speed.
